(19) United States
(12) Patent Application Publication
(10) Pub. No.: US 2026/0339522 A1
(43) Pub. Date: Oct. 29, 2026

(54) APPARATUS AND METHOD FOR DYNAMIC FLASH MEMORY SCRUBBING

(71) Applicant: QUALCOMM Incorporated, San Diego, CA (US)

(72) Inventors: Madhu Yashwanth BOENAPALLI, Hyderabad (IN); Sravani DEVINENI, Hyderabad (IN); Tirupathi Venkateswara Reddy ASODI, Hyderabad (IN); Sai Praneeth SREERAM, Anantapur (IN)

(21) Appl. No.: 19/193,210

(22) Filed: Apr. 29, 2025

(51) Int. Cl. G06F 3/06

(52) U.S. Cl. CPC G06F 3/0616; G06F 3/064; G06F 3/0679

(57) ABSTRACT

Aspects of the present disclosure are directed to techniques and procedures for improved scrubbing operations of nonvolatile memory devices. The techniques can identify memory blocks that are more prone to bit flips based on the history of error correction operated on the memory blocks. The techniques can identify one or more vulnerable memory blocks of a plurality of memory blocks, the one or more vulnerable memory blocks being suspectable to a bit flip based on an error history of a plurality of memory blocks within a nonvolatile memory. Then the techniques can initiate a targeted scrubbing operation to the one or more vulnerable memory blocks.

### TECHNICAL FIELD

The technology discussed below relates generally to a data storage device, and more particularly, to techniques for dynamic nonvolatile memory scrubbing.

### INTRODUCTION

A data storage device may use volatile memories and nonvolatile memories for storing data. A volatile memory cannot retain data stored therein at power-off, but a nonvolatile memory can retain data stored therein at power-off. Some examples of volatile memories include static random access memory (SRAM), dynamic RAM (DRAM), and synchronous DRAM (SDRAM). Some examples of nonvolatile memories include a read-only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), and a ferroelectric RAM (FRAM).

The flash memory device is widely used as a storage device in various devices and applications, for example, computing devices, mobile devices, and wireless communication devices to store large quantities of data. In some aspects, a flash memory-based storage device can be implemented as a universal flash storage (UFS) defined by the JEDEC (Joint Electron Device Engineering Council) standard. Flash memory devices (e.g., NAND flash) have a limited lifespan, and their individual memory blocks can wear out over time as they are repeatedly written and erased. Scrubbing refers to a proactive process where the memory system checks and corrects bit errors (e.g., bit flips) before they cause data loss in the memory device. A scrubbing process can include reading data from a flash memory, checking the data for bit errors, correcting the errors (if needed), and relocating worn-out data blocks to healthy ones (wear leveling). Scrubbing can prevent data loss, extend device lifespan, reduce chance of unrecoverable read errors, and improve data integrity and reliability.

### BRIEF SUMMARY

The following presents a summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a form as a prelude to the more detailed description that is presented later.

One aspect of the disclosure provides a data storage device. The data storage device includes: a nonvolatile memory including a plurality of memory blocks and a memory controller. The memory controller is configured to: identify one or more vulnerable memory blocks of the plurality of memory blocks, the one or more vulnerable memory blocks being suspectable to a bit flip based on an error history of the plurality of memory blocks; and initiate a targeted scrubbing operation to the one or more vulnerable memory blocks.

One aspect of the disclosure provides a method of operating a data storage device. The method includes identifying one or more vulnerable memory blocks of a plurality of memory blocks within a nonvolatile memory, the one or more vulnerable memory blocks being suspectable to a bit flip based on an error history of the plurality of memory blocks; and initiating a targeted scrubbing operation to the one or more vulnerable memory blocks.

One aspect of the disclosure provides a data storage device. The data storage device includes: means for identifying one or more vulnerable memory blocks of a plurality of memory blocks within a nonvolatile memory, the one or more vulnerable memory blocks being suspectable to a bit flip based on an error history of the plurality of memory blocks; and means for initiating a targeted scrubbing operation to the one or more vulnerable memory blocks.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1 is a block diagram illustrating a data storage system according to some aspects of the present disclosure.

FIG. 2 is a block diagram illustrating some components of a memory controller according to some aspects of the disclosure

FIG. 3 is a diagram illustrating a portion of a nonvolatile memory according to some aspects of the disclosure.

FIG. 4 is a flow chart illustrating a memory scrubbing procedure according to some aspects of the disclosure.

FIG. 5 is a flow chart illustrating a dynamic scrubbing process of nonvolatile memory according to some aspects of the disclosure.

FIG. 6 is a flow chart illustrating a process for identifying memory blocks that have a high probability of bit flips according to some aspects of the disclosure.

FIG. 7 is a flow chart illustrating a process for refreshing data in nonvolatile memory according to some aspects of the disclosure.

FIG. 8 is a flow chart illustrating a dynamic memory scrubbing method according to some aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, these concepts may be practiced without these specific details. In some instances, well-known structures and components are shown in block diagram form in order to avoid obscuring such concepts.

The terminology used herein is for the purpose of describing particular examples only and is not intended to be limiting. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, processes, operations, elements, and/or components, but do not preclude the presence or addition of one or more other features, integers, processes, operations, elements, components, and/or groups thereof.

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the examples described herein, the corresponding form of any such examples may be described herein as, for example, “logic configured to” perform the described action.

Some aspects of the disclosure provide a data storage device that uses nonvolatile memory (NVM) to store data. An example of nonvolatile memory is flash memory (e.g., NAND-based flash memory). In one example, the data storage device can be implemented as a Universal Flash Storage (UFS) device or any data storage device that uses flash memory (e.g., NAND) as the main storage. To enhance data reliability and extend the operational lifespan of flash memory in a data storage device, a flash scrub feature can be implemented at the device. Flash scrubbing can address inherent limitations of flash memory, such as the tendency for memory blocks to degrade at runtime, the deterioration of pages after a certain number of read, write and erase cycles, and the gradual decay of stored data over time. Furthermore, the rate of data degradation is known to accelerate significantly under elevated temperature conditions. To mitigate these effects and ensure data integrity over a target lifespan of the data storage device, flash scrubbing employs various techniques, including periodic data refresh operations, dynamic bad block management, and wear leveling algorithms to optimize memory usage and distribute wear evenly across the flash memory.

In some examples, a data storage device can perform memory scrubbing operations on nonvolatile memory (e.g., NAND flash) by monitoring the elapsed time since the previous scrub cycle and initiating a new scrub when a predefined scrub timer threshold is met. In some aspects, a flash memory can have various memory partitions, such as a code partition, a secondary boot loader (SBL) partition, and an embedded file system (EFS) partition, and the scrubbing process can be customized for each partition accordingly. For example, the different partitions can have different scrubbing frequencies or trigger conditions.

Traditional scrubbing algorithms typically operate on a fixed schedule. For example, over a projected device 15 years lifecycle of the flash memory, scrubbing can be triggered approximately 45 times when using a default interval of once every four months. However, if the number of flipped bits that occur between two scrubbing intervals exceeds the maximum error correction capability of the memory device (e.g., error correction code (ECC) correction), the data may become unrecoverable. In NAND flash, a bit flip can occur when a single binary digit (bit) unexpectedly changes its state, flipping from 0 to 1 or from 1 to 0. If a memory block has an uncorrectable ECC error, it is considered as a data corruption and cannot be recovered. Uncorrectable ECC error can lead to device crashes and bootup errors.

Aspects of the present disclosure provide various techniques, apparatuses, and methods that improve the scrubbing operations of flash memory devices. The techniques can identify memory blocks that are more prone to bit flips based on the history of ECC correction operated on the memory blocks.

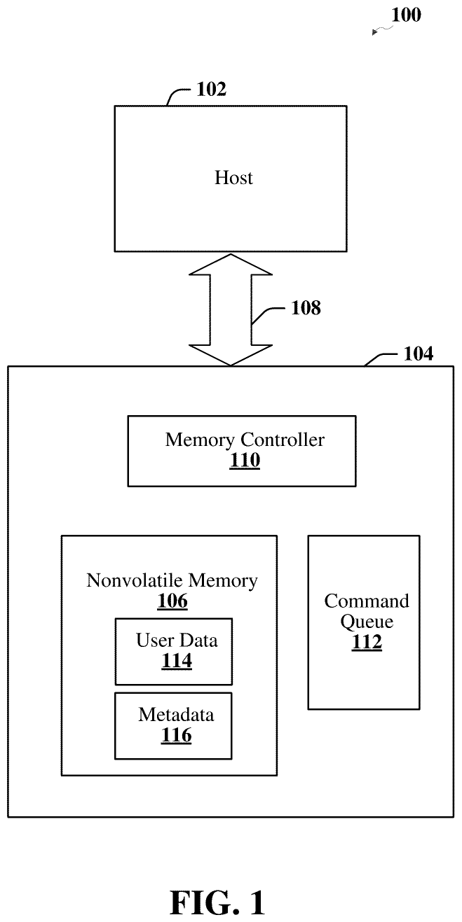

FIG. 1 is a block diagram illustrating a data storage system 100 according to some aspects of the disclosure. A data storage system 100 may include a host 102 and a data storage device 104. In some examples, the data storage system 100 may be implemented in a portable computer, a tablet, a smartphone, a wearable device, a wireless communication device, a base station, a network entity, etc. In some aspects, the host 102 may be a processor such as a central processing unit (CPU), a graphical processing unit (GPU), a digital signal processor (DSP), a controller, a microcontroller, an application processor (AP), a neural processing unit (NPU), a field-programmable gate array (FPGA), etc.

The host 102 can use the data storage device 104 to store data for various operations. In some aspects, the data storage device 104 may store data using nonvolatile memory 106 (e.g., NAND flash). In some aspects, the data storage device 104 can be compliant with the Universal Flash Storage (UFS) specification defined by JEDEC (Joint Electron Device Engineering Council). In one example, the host 102 (e.g., UFS host) can write data to and read data from the storage device 104 using a storage interface 108 (e.g., UFS interface). In some examples, the storage interface 108 can be implemented using various interface standards, for example, Peripheral Component Interconnect Express (PCIe), Universal Chiplet Interconnect Express (UCIe), Serial Advanced Technology Attachment (ATA), etc. The host 102 can send a write command (with write data) to the storage device 104 in order to store the data in the storage device 104. To read data from the storage device 104, the host 102 can send a read command to the storage device 104 and receive data from the storage device 104. In one example, the host 102 and the storage device 104 can exchange information in the form of Universal Flash Storage Protocol Information Units (UPIUs). A UPIU can include various information transferred via the interface (e.g., interface 108) between the host 102 and the storage device 104. For example, the UPIU can include commands, data read from or written to the storage device 104, status information, and/or control information. For example, the status information in the UPIU can provide information about the status of the storage device 104 or the progress of a particular operation (e.g., write data to or read data from the storage device 104). The status information can provide details about whether an operation was successful, whether an error occurred, and what type of error occurred. The control information in the UPIU can be used to manage the communication between the storage device 104 (e.g., a UFS device) and the host 102. For example, the control information can include information about the device's configuration, power management, and other parameters related to data transfer between the host and the data storage device.

In some aspects, the data storage device 104 may include a memory controller 110 for controlling various operations of the nonvolatile memory 106. In one example, the memory controller 110 may be a Flash memory controller. The memory controller 110 can manage the data flow between the nonvolatile memory 106 and the host 102. In some aspects, the memory controller 110 may include a host controller interface (HCI) for communicating with the host 102 via the storage interface 108. In some aspects, the HCI may be a separate entity from the memory controller 110. In some aspects, the memory controller 110 is responsible for performing various tasks such as error correction, wear leveling, garbage collection, power management, etc. For example, the memory controller 110 may write data to or read data from the nonvolatile memory 106 (e.g., NAND Flash) in response to a command (e.g., a UFS read or write command) received from the host 102 via the storage interface 108. In some aspects, the memory controller 110 may be implemented using a processor such as a microprocessor, a microcontroller, an FPGA, etc. In some aspects, the memory controller 110 can be implemented using a combination of hardware and software to manage the transfer of data between the host 102 and the nonvolatile memory 106. In some examples, the memory controller 110 can include memory buffers, data converters, and interfaces for communication with the host 102 and the nonvolatile memory 106.

In one example, when the memory controller 110 receives a write command and write data from the host 102, the memory controller 110 can store the received data in the nonvolatile memory 106 according to the write command. In one example, when the memory controller 110 receives a read command from the host 102, the memory controller 110 can read data stored in the nonvolatile memory 106 according to the read command. Then, the memory controller 110 can provide the read data to the host 102, for example, via the interface 108. The data storage device 104 can include a command queue 112 that stores the commands (e.g., write commands and read commands) and data received from the host 102. The command queue 112 can help improve the performance of the storage device 104 by allowing it to process multiple commands simultaneously and/or optimize the order in which the commands are executed.

In some aspects, the nonvolatile memory 106 can include NAND flash memory that is organized in a number memory blocks that can enable parallel operations. Each memory block includes a number of pages. A memory block (or simple block) is the smallest unit that can be erased in NAND flash. A page is the smallest unit for read and write operations. A page can include user data 114 and metadata 116 (e.g., error correction codes).

In some aspects, the data storage device 104 may further include other storage space, for example, a write buffer, a cache memory, a reserved area, a metadata area for storing metadata, in addition to the command queue and the nonvolatile memory illustrated in FIG. 1. However, for convenience of description, additional description associated with the other storage space will be omitted (or minimized), and the below description will be focused on the nonvolatile memory where user data and metadata are stored.

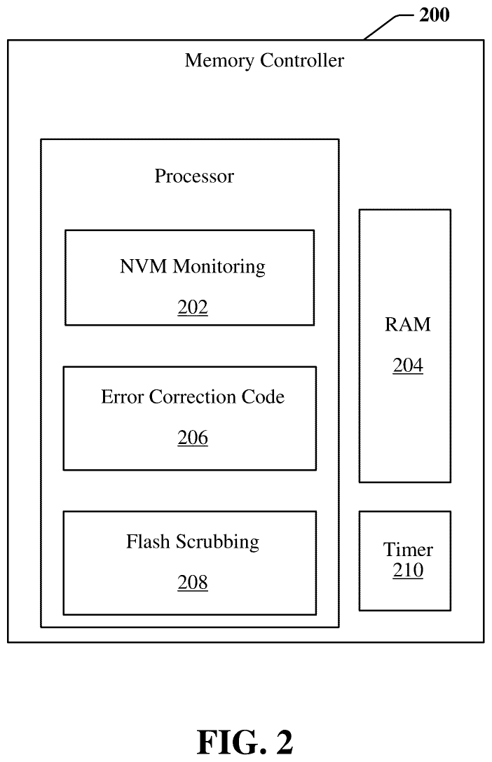

FIG. 2 is a block diagram illustrating some components of a memory controller 200 according to some aspects of the disclosure. In one example, the memory controller 200 can be the memory controller 110 of FIG. 1. In some aspects, the memory controller 200 has a nonvolatile memory (NVM) monitoring block 202 that can be configured to perform various functions and processes for accessing and maintaining data integrity in a nonvolatile memory (e.g., NAND flash memory). The NVM monitoring block 202 can be implemented in software, hardware, and/or a combination of software and hardware. The NVM monitoring block can keep track of the program and erase (P/E) count and error history (e.g., bit flips, ECC corrections, etc.) of the nonvolatile memory using a combination of metadata, counters, and software. For example, each block of nonvolatile memory can have P/E cycle information stored in metadata (e.g., metadata 116 of FIG. 1). This P/E cycle information tracks how many times that specific memory block has been erased and programmed. For example, the P/E cycle information can be stored in a random access memory 204 (e.g., static random access memory (SRAM), dynamic random access memory (DRAM), etc.). Further, the P/E cycle information can be stored redundantly in reserved areas (e.g., metadata 116 of FIG. 1) of the nonvolatile memory for persistence across power cycles.

The memory controller 200 can include an error correction code (ECC) block 206 that can be implemented in software, hardware, and/or a combination of software and hardware. The ECC block can be configured to perform various ECC related functions, for example, the ECC block can use ECC algorithms (e.g., Hamming codes, Bose-Chaudhuri-Hocquenghem (BCH) codes, Low-density parity-check (LDPC) codes, etc.) to check for bit errors in the nonvolatile memory (e.g., NAND flash). The ECC block 206 can correct a defined number of bit errors or bit flips per codeword. When writing data to nonvolatile memory, the ECC block 206 can calculate the ECC parity bits for each data page and store the ECC parity bits in an area (e.g., metadata 116 of FIG. 1) of the nonvolatile memory for ECC data. If a memory block has an uncorrectable ECC (UECC) error, it is considered as a data corruption and cannot be recovered. An error (e.g., bit flips) becomes uncorrectable when the number of bit errors exceeds the correction capability of the ECC algorithm used by the memory controller. For example, if a 16-bit codeword has two bit flips, it becomes an UECC error. A bit flip occurs when a single binary digit (bit) in the memory unexpectedly changes its state, flipping from 0 to 1 or from 1 to 0. A bit flip can be caused by, for example, long data retention, fast cycling, excessive usage, read disturb, and/or elevated temperature.

In some aspects, the ECC block 206 also can monitor the health and reliability of the nonvolatile memory by tracking the raw bit error rate (RBER) of the memory blocks. Specifically, whenever the memory controller reads data from the nonvolatile memory, the ECC block 206 can compare the retrieved ECC data against recalculated ECC to identify and count bit errors. Each detected bit error can increment a running error count, which the memory controller can store and maintain, for example, within an internal status register or monitoring database. By aggregating these counts over time and across multiple memory blocks, the ECC block 206 can calculate and update the raw bit error rate, providing real-time insight into memory degradation. This continuous tracking enables proactive measures, such as triggering scrubbing operations or scheduling data refresh cycles, to ensure optimal memory reliability and extend device longevity.

In some aspects, the memory controller can have a flash scrubbing block 208 that can be implemented in software, hardware, and/or a combination of software and hardware. The flash scrubbing block 208 can be configured to perform various memory scrubbing related functions. For example, the flash scrubbing block 208 can be configured to perform periodic memory scrubbing in order to preserve data integrity and reduce the risk of data corruption in nonvolatile memory (e.g., NAND flash). The flash scrubbing block 208 can maintain a record of the elapsed time since the last scrubbing event and automatically initiate a new scrubbing cycle once a predefined scrub timer threshold is met. The memory controller can use one or more timers (e.g., a timer 210) to keep track of the time interval between scrubbings. Periodic scrubbing ensures that data stored in the flash memory is regularly refreshed or validated, particularly in regions that may be susceptible to data degradation over time.

Furthermore, the scrubbing process can intelligently adapt to accommodate the specific characteristics and operational constraints of different memory partitions, for example, code partitions, secondary boot loader (SBL) partitions, and embedded file system (EFS) partitions. In particular, due to architectural and functional differences between code partitions, SBL partitions, and EFS partitions, the scrubbing process can vary for each partition type. For instance, the EFS partition, being part of the root file system, can manage its own scrubbing operations independently. In contrast, the SBL partition requires scrubbing to occur within specific flash memory blocks that reside within the addressable range of the PBL. This constraint arises because the PBL has limited access capabilities and cannot directly address or initiate operations beyond the designated bootable image region. As such, targeted scrubbing logic can be implemented to ensure SBL data integrity while remaining compatible with the PBL's operational boundaries.

A time-based or periodic scrubbing algorithm can operate on a fixed, periodic schedule. For example, a static scrubbing interval can be configured by an original equipment manufacturer (OEM) to accommodate various reliability requirements of the data storage device. During the time interval between two scrubbing operations, if any bit flip occurs (e.g., due to mechanisms such as charge leakage, read disturb, or retention degradation), and the number of bit errors exceeds the correction capability of the implemented ECC algorithm, the data affected becomes unrecoverable. For instance, in systems utilizing an ECC scheme capable of correcting up to 8 errors in a 16-bit codeword, the presence of more than 8 bit errors in such a codeword would render the data permanently corrupted, as the ECC mechanism would be unable to reconstruct the original information. In some applications, excessive bit flips between scrubbing intervals have been observed with high frequency in the absence of more aggressive or adaptive scrubbing strategies.

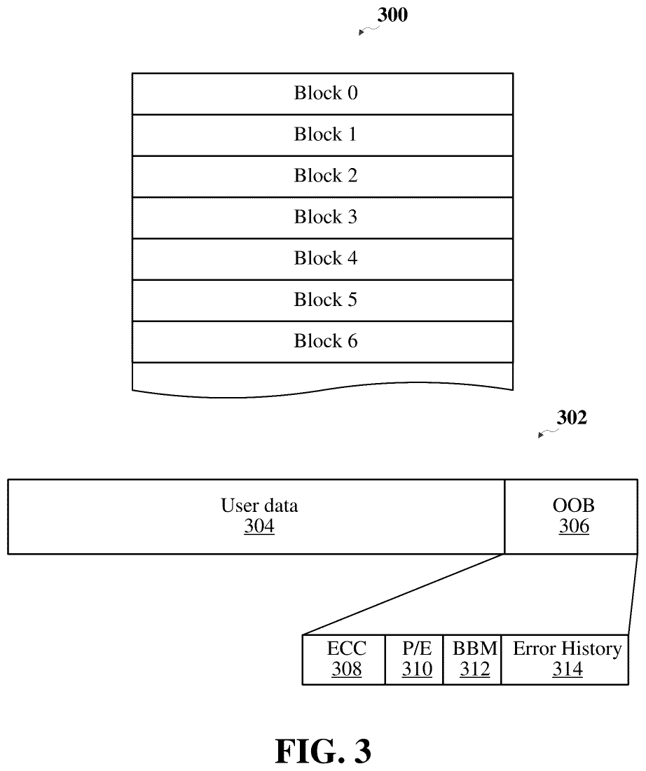

FIG. 3 is a diagram illustrating a portion of a nonvolatile memory 300 according to some aspects of the disclosure. In one example, the nonvolatile memory 300 can be the nonvolatile memory 106 of FIG. 1. The nonvolatile memory 300 has a plurality of memory cells (e.g., NAND cells) that are grouped into memory blocks (e.g., block 0 through block 6 shown in FIG. 3), and the cells in each block are erasable together as part of a single erase operation, typically simultaneously. In NAND flash memory, the memory block is the minimum unit of erase. In some aspects, each block 302 can include a number of pages that can be written and read.

In some aspects, each block can include a user data area 304 and an out-of-band (OOB) area 306. The user data area 304 can store application data, operating system (OS) files, documents, multimedia, system configurations, etc., for a host (e.g., host 102 of FIG. 1). For example, the user data can be stored in one or more pages (a page is the smallest writable unit). The OOB area 306 can store various management information of the memory block, for example, ECC, bad block marker (BBM), wear-leveling information, metadata, etc. The memory controller can calculate the ECC of the user data stored in the block. When the memory controller reads the user data from the block, the ECC is also read from the OOB area. The OOB can include information related to the program/erase (P/E) cycles 310 experienced by the block. The memory controller can monitor the health of the block and perform wear-leveling based on the P/E cycles recorded. The memory controller can update the P/E information (e.g., P/E cycle counts) after each P/E cycle. The memory controller can use the P/E cycle information to proactively prevent data loss or corruption by moving the user data from a block with a P/E cycle count that exceeds a predetermined threshold or design limit.

A bad block marker (BBM) (e.g., BBM 312) can indicate if a block has been marked unreliable, defective, or no longer suitable for data storage. During operation, the memory controller can mark a block as a bad block when it becomes unreliable (e.g., persistent ECC errors, frequent bit flips, repeated erase/program failure). Once the block is marked as a bad block in its corresponding BBM in the OOB, the memory controller does not use that block for data storage. The memory controller can move the user data from the bad block to other block.

The OOB 306 also can store error history 314 that can be used to determine if a memory block is more prone to bit flips. For example, the error history 314 can include the past history of ECC corrections of a block. In some aspects, the memory controller can use the error history 314 to determine whether or not to initiate a targeted scrubbing operation to the block. A targeted scrubbing operation is dynamic and aperiodic as compared to a periodic or static scrubbing operation that occur periodically based on, for example, a time-based event (e.g., timer). When a block experiences too many bit flips beyond the capability of ECC correction between two periodical scrubbing operations, data can be lost in that block. In some aspects, the memory controller can scan the memory blocks, for example periodically, to identify a vulnerable block that is more prone to bit flips based on the error history 314. During a block scan, the memory controller can read the OOB 306 to obtain the error history 314 for each block. Then the memory controller can proactively trigger a scrubbing operation to move the data away from the vulnerable block to other blocks to avoid potential data loss based on the error history.

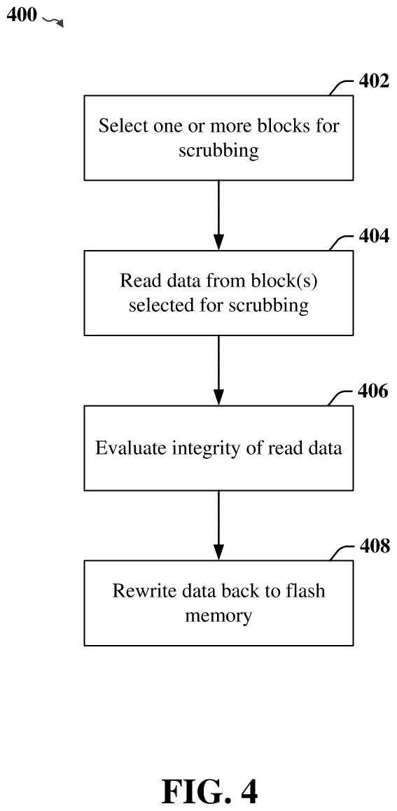

FIG. 4 is a flow chart illustrating a memory scrubbing procedure 400 according to some aspects of the disclosure. In some aspects, the scrubbing procedure 400 can be performed by the memory controller described above in relation to FIGS. 1 and/or 2 based on various triggering methods, for example, elapsed time, P/E cycle counts, and/or error history (e.g., ECC errors). At predetermined intervals (e.g., periodic scrubbing) or in response to a triggered scrubbing event (e.g., targeted scrubbing), the memory controller can perform the scrubbing procedure 400 on a nonvolatile memory (e.g., NAND flash memory). For periodic or static scrubbing, the memory controller can perform the scrubbing procedure 400 according to a timer (e.g., timer 210 of FIG. 2) or timestamp log for each block or group of blocks of the memory. For targeted scrubbing, the memory controller can perform the scrubbing procedure based on a certain trigger event (e.g., error history 314 of FIG. 3 exceeding a predetermined threshold). The memory controller is configured to perform the scrubbing procedure at sufficient frequency such that bit errors (e.g., bit flips) of a block do not exceed the ability of ECC recovery schemes implemented at the memory.

At block 402, the memory controller can select one or more memory blocks for scrubbing. For example, the memory controller can select all the memory blocks that currently store valid data. In another example, the memory controller can select a memory block that has not been scrubbed for a predetermined period of time based on a timestamp of the last scrubbing performed. For periodic scrubbing, the memory controller can select all memory blocks that contain data. For targeted scrubbing, the memory controller can select only vulnerable blocks based on the error history of the memory blocks.

At block 404, the memory controller can read data (scrub read) from the memory block(s) selected for scrubbing. For example, a scrub read may not be directly related to any particular host operation (e.g., read operations from the host 102 of FIG. 1) but can be executed in a similar manner as a memory read operation from the host. For example, the memory controller can issue a read command to the nonvolatile memory to read user data and OOB information (e.g., ECC bits, P/E count, and error history) from the selected memory blocks.

At block 406, the memory controller can evaluate the integrity of the read data. As part of the scrub read, the memory controller can calculate a new ECC from the data read from the memory blocks and compare with the previous ECC that was earlier stored (e.g., metadata 116 of FIG. 1) in the OOB along with the data during programming. When the memory controller finds no bit error or a small number of errors that can be corrected by an ECC correction algorithm, the read data is considered valid. The memory controller can read each page within the selected block and run the ECC algorithm on each page to detect any bit errors. The memory controller can correct any error found error if it is within the ECC algorithm limits. If an uncorrectable error is found, the memory controller can log the error and mark the block as bad (e.g., BBM 312 of FIG. 3).

At block 408, the memory controller can rewrite the read data back to the memory blocks (e.g., blocks) of the nonvolatile memory. Rewriting the data (with or without correction) to the memory block refreshes the charge in the memory cells (e.g., NAND cells), restoring data integrity and reducing the chance of potential bit flips and data lost. In some aspects, the memory controller can write the read data to the original blocks or different blocks when the original blocks are vulnerable based on past error history and/or cell condition. The memory controller can temporarily hold the data in an internal buffer (e.g., RAM 204 of FIG. 2) or a scrub (spare) portion of the partition. Then the memory controller can erase the original block being scrubbed. After the erasure of the original block, the memory controller can write the data back into the memory, recalculate fresh ECC parity bits, and update the OOB information (e.g., ECC, P/E counters, etc.). Any block that consistently generates errors beyond thresholds can be marked as a bad block (BBM updated in OOB). The memory controller can also update a scrub timestamp after each successful scrubbing operation.

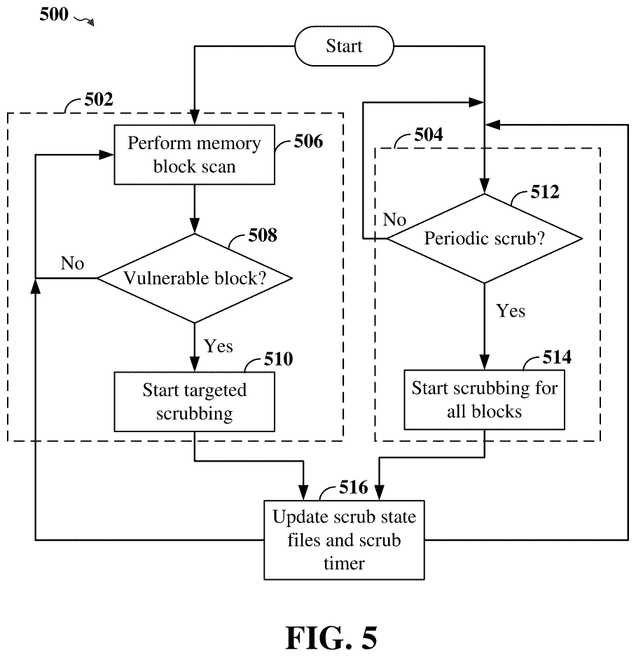

FIG. 5 is a flow chart illustrating a dynamic scrubbing process 500 of nonvolatile memory according to some aspects of the disclosure. In some aspects, the dynamic scrubbing process 500 can be performed by any of the memory controllers described above in relation to FIGS. 1 and/or 2 to ensure data integrity and reliability of memory blocks of nonvolatile memory (e.g., nonvolatile memory 106 of FIG. 1). The dynamic scrubbing process 500 uses both targeted scrubbing 502 and static scrubbing 504 to reduce the potential of bit flips, specifically, between periodic scrubbings. In other aspects, the dynamic scrubbing process can be performed by any memory controller to scrub a nonvolatile memory (e.g., NAND flash).

At block 506, the memory controller can perform a memory block scan operation, which analyzes the health or error history of individual memory blocks (e.g., NAND blocks) based on their OOB information (e.g., OOB 306 of FIG. 3). For example, the error correction history (error history 314 of FIG. 3) can indicate the likelihood of future bit flips within each specific memory block. The memory controller can perform the memory block scan operation (e.g., NAND scan) at a predetermined frequency. In one example, the scan frequency can be set by the manufacturer. In one example, the memory controller can set the scan frequency during a bootup sequence. For example, the error correction history can indicate the number of past ECC corrections, ECC failures, etc., of the memory blocks. Based on the error correction history, the memory controller can determine the raw bit error rate of each block. For example, the raw bit error rate (RBER) of each block refers to the number of bit errors occurred (irrespective of ECC correction) relative to the total number of bits stored in that memory block. A low RBER indicates healthy memory blocks, on the contrary, a high RBER suggests potential block degradation, nearing the end of useful life, and/or manufacturing issues.

At block 508, after the memory scan operation, the memory controller can determine whether or not one or more memory blocks are identified as being vulnerable and have a higher probability of imminent bit flips based on the error correction history. For example, the memory controller can determine that a memory block is vulnerable when its RBER is greater than a predetermined threshold or trigger. The RBER threshold depends upon the memory variants. For example, NAND can support 2K or 4K page sizes. For both variants, the RBER thresholds can be 4-bit, 8-bit, or 16-bit. For example, the threshold can be set to an effective value to reduce the likelihood that a memory block that will experience an amount of bit flips that are beyond the ECC correction capability of the memory block.

At block 510, if one or more vulnerable memory blocks are identified, the memory controller can initiate a targeted scrubbing process on that particular memory block(s). This targeted scrubbing process is selective and aperiodic in nature and is not based on a fixed or periodic scrubbing schedule. The targeted scrubbing process can be similar to the scrubbing procedure 400 of FIG. 4, for example, including reading the data from a memory block, correcting any detected errors through ECC mechanisms if needed, and subsequently rewriting the corrected data back into the memory block to refresh and reinforce data reliability.

Concurrently, the memory controller can perform periodic or static scanning of memory blocks. At block 512, the memory controller can decide whether or not to perform a periodic scrubbing process. For example, the memory controller can use a scrub timer or counter (e.g., the timer 210 of FIG. 2) to determine the time elapsed between periodic scrubbings. The memory controller can start a periodic scrubbing process at regular intervals. At block 514, when the periodic scrubbing process is triggered (e.g., based on a timer or counter), the memory controller can perform a periodic scrubbing operation encompassing all memory blocks (e.g., NAND blocks), for example, in one or more partitions. During periodic scrubbing, the memory controller can read the data from each memory block, check, correct any errors found, and rewrite the data back to the block, thus refreshing the memory blocks. In some aspects, the memory controller can use the scrubbing procedure 400 of FIG. 4 to perform periodic scrubbing. In some aspects, the memory controller can use different periods or frequencies for scrubbing different partitions of a nonvolatile memory. For example, the nonvolatile memory can have a code partition, an SBL partition, and an EFS partition, and the memory control can perform the periodic scrubbing process using different periods for these partitions.

At block 516, following either a targeted or periodic scrubbing operation, the memory controller can update a scrub state file and reset the scrub timer accordingly. The scrub state file can track the progress and status of scrubbing operations. For example, the scrub state file can record which block(s) have already been scrubbed so that the memory controller can resume scrubbing from the last known point in case of interruption (e.g., power loss or system reboot). In some aspects, the memory controller can keep the scrub state file in a working memory or buffer (e.g., RAM 204 of FIG. 2) and save a copy of the scrub state file in the nonvolatile memory (e.g., metadata 116 of FIG. 1) in case of interruption.

Because targeted scrubbing operations are not timer-based, targeted scrubbing can occur before the timer used for periodic scrubbing is lapsed. In some aspects, to prevent wear-out from excessive P/E cycles, the memory controller can set a minimum time interval between two targeted scrubbing operations. After each targeted scrubbing operation, the memory controller can update the last scrub time stored in metadata (e.g., scrub state file), which then determines when the next scrubbing operation (e.g., periodic scrubbing) can be performed based on the new timestamp (last scrub time).

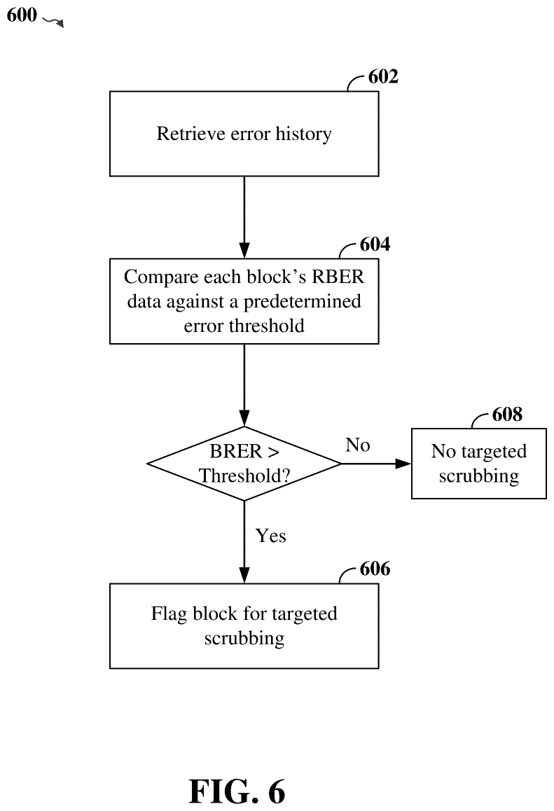

FIG. 6 is a flow chart illustrating a process 600 for identifying memory blocks that have a high probability of bit flips according to some aspects of the disclosure. For example, a memory controller (e.g., the memory controller of FIG. 1 or FIG. 2) can use the process 600 to determine whether or not a memory block (e.g., NAND block) is more likely to experience uncorrectable bit flip based on historical error data (e.g., RBER) of the memory block.

At block 602, the memory controller can retrieve the error history of a memory block. For example, the memory controller can check the RBER history for each memory block (e.g., NAND block) that can be stored as metadata (e.g., metadata 116 of FIG. 1, error history 314 of FIG. 3). At block 604, the memory controller can compare each block's historical RBER data against a predetermined error threshold. If the RBER for any specific block surpasses the threshold, it indicates a heightened risk of bit flips in the near future. At block 606, when the memory controller determines that the RBER of one or more memory blocks exceeds the error threshold, the memory controller flags that particular block(s) as requiring immediate attention. For example, the memory controller can initiate a targeted scrubbing operation as described above in FIG. 5, specifically for the flagged block(s). Conversely, at block 608, if a block's RBER remains below the error threshold, the block is not flagged for targeted scrubbing. A block not flagged for targeted scrubbing can still be scrubbed during periodic scrubbing (e.g., static scrubbing 504 of FIG. 5). The above-described error threshold based decision-making process enables proactive and efficient management of memory block reliability using targeted scrubbing.

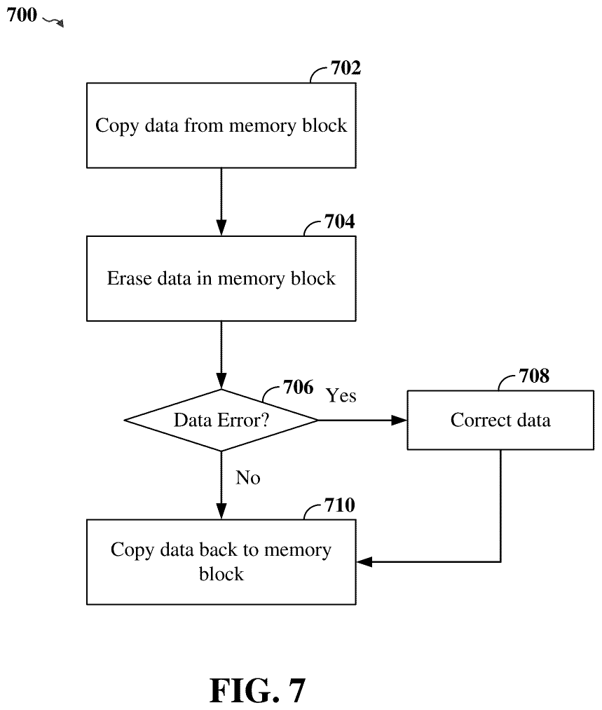

FIG. 7 is a flowchart illustrating an exemplary process 700 for refreshing data stored in nonvolatile memory, such as NAND flash memory, in accordance with aspects of the present disclosure. In some implementations, the process 700 may be executed by a memory controller (e.g., the memory controller described with reference to FIG. 1 or FIG. 2) as part of a memory maintenance or data scrubbing operation. Scrubbing may be performed periodically or in response to a triggering condition, such as detection of threshold error rates. Refreshing data in memory blocks can mitigate data degradation due to factors such as charge leakage, repeated P/E cycles, etc. The process 700 may be applied to one or more memory blocks (e.g., NAND blocks) located in one or more partitions of the nonvolatile memory.

At block 702, the memory controller selects a first memory block for scrubbing and initiates copying of all data stored in the first memory block to a second memory block. The second memory block can be a newly allocated block or spare block that has been previously erased and is in a ready-to-program state (e.g., a clean NAND block). The copy operation can include reading each valid page of data from the first memory block and writing it to a corresponding page location in the second memory block.

At block 704, upon successful completion of the copy operation, the memory controller can erase the first memory block. The erase operation prepares the block for reuse in subsequent memory operations and may include updating metadata to mark the block as erased or available in a free block pool.

At block 706, the memory controller can evaluate the integrity of the data that was read from the first memory block. In one example, the memory controller can recalculates an error correction code (ECC) or checksum associated with the read data and compares it with a stored ECC value to determine whether any bit errors (e.g., bit flips or retention errors) are present. For example, the memory controller can perform this error-checking process on a per-page basis. At block 708, if one or more bit errors are detected, the memory controller can attempt to correct the errors using an ECC algorithm or other error recovery mechanism. The corrected data can then temporarily stored, either in a buffer or a spare area of memory, for further processing.

At block 710, the memory controller can copy the validated and, if applicable, corrected data from the second memory block (or from the buffer) back to the original physical location, i.e., the first memory block. This write-back step effectively refreshes the data in the same memory block, thereby reducing the risk of future data corruption due to accumulated bit errors.

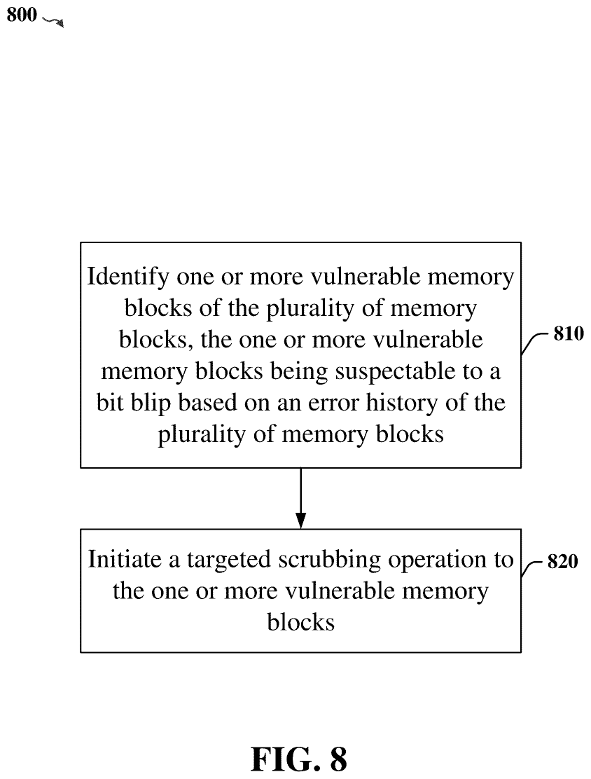

FIG. 8 illustrates a flow chart of a dynamic memory scrubbing method 800 according to some aspects of the present disclosure. In one example, the scrubbing method 800 can be performed using a data storage system as described in relation to FIGS. 1 and 2.

A memory controller can determine an error history for a plurality of memory blocks in a nonvolatile memory (e.g., NAND flash memory or other solid-state storage), each of which can be monitored for data errors over time. For example, the memory controller of FIG. 1 or FIG. 2 can provide a means (e.g., NVM monitoring 202 of FIG. 2) to compile historical error data for the memory blocks by retrieving error history (e.g., counts of error-correction events or logged instances of single-bit errors that were detected and corrected in each block during operation). This error history (e.g., error history 314 of FIG. 3) may be maintained as a data structure or log associated with the memory block, recording information such as the number of bit errors or ECC corrections that have occurred in each block over a given period. Based on the error history, the memory controller has a record of which memory blocks have experienced data errors (e.g. bit flips) and how frequently those errors have occurred, providing a foundation for identifying problematic blocks in subsequent steps.

At block 810, the memory controller can identify one or more vulnerable memory blocks of the plurality of memory blocks, the one or more vulnerable memory blocks being suspectable to a bit flip based on the determined error history of the plurality of memory blocks. In this context, frequent bit flip events may indicate an underlying reliability concern if such events become too frequent. Using the error history, the memory controller can compare the number or rate of errors (e.g., bit flips) in each block against a predetermined error threshold. If a particular block has experienced an unusually high number of bit errors or increasing frequency of corrections within a recent timeframe, the memory controller can mark that block as vulnerable.

In some aspects, the memory controller can provide a means (e.g., ECC block 206 of FIG. 2) to calculate a RBER for each block. Blocks that exceed an RBER threshold can be flagged as vulnerable. The memory controller can isolate the memory blocks that are susceptible to bit flips, meaning they have shown a propensity for repeated minor errors and are at greater risk of developing more serious data integrity issues (such as accumulating errors that could eventually become uncorrectable). After the memory controller identifies one or more memory blocks as vulnerable, these blocks can be targeted for remedial action, for example, targeted scrubbing as described above in relation to FIG. 5.

In block 820, the memory controller can initiate a targeted scrubbing operation directed at the one or more memory blocks identified as vulnerable. For example, the memory controller can provide a means (e.g., flash scrubbing block 208 of FIG. 2) to initiate the targeted scrubbing operation. For example, targeted scrubbing can be the same as targeted scrubbing process described above in relation to FIGS. 3-7. Targeted scrubbing can reduce uncorrectable bit flips between routine or periodic scrubbings. Unlike a routine scrubbing that periodically covers the entire memory, this targeted scrubbing approach can focus only on the blocks that have been flagged as vulnerable (susceptible to errors).

In other aspects, the method may be adapted to suit other data storage devices.

The following provides an overview of examples of the present disclosure.

A first aspect of the disclosure provides a data storage device. The data storage device comprises: a nonvolatile memory comprising a plurality of memory blocks; and a memory controller configured to: identify one or more vulnerable memory blocks of the plurality of memory blocks, the one or more vulnerable memory blocks being suspectable to a bit flip based on an error history of the plurality of memory blocks; and initiate a targeted scrubbing operation to the one or more vulnerable memory blocks.

A second aspect of the disclosure, alone or in combination with the first aspect, wherein the memory controller is further configured to periodically scan the plurality of memory blocks to determine the error history.

A third aspect of the disclosure, alone or in combination with the first aspect, wherein the error history comprises historical bit error rate (BER) data of the plurality of memory blocks.

A fourth aspect of the disclosure, alone or in combination with any of the first to third aspects, wherein the targeted scrubbing operation comprises moving data from the one or more vulnerable memory blocks to one or more other memory blocks of the plurality of memory blocks.

A fifth aspect of the disclosure, alone or in combination with any of the first to third aspects, wherein the targeted scrubbing operation comprises correcting detected errors using error correction code (ECC) algorithms in the targeted scrubbing operation.

A sixth aspect of the disclosure, alone or in combination with any of the first to third aspects, wherein the memory controller is further configured to update a scrubbing timestamp stored in a scrub state file after the targeted scrubbing operation.

A seventh aspect of the disclosure, alone or in combination with the sixth aspect, wherein the memory controller is further configured to update error correction outcomes of the one or more vulnerable memory blocks in the nonvolatile memory.

An eighth aspect of the disclosure, alone or in combination with the sixth aspect, wherein the memory controller is further configured to mark the one or more vulnerable memory blocks in the nonvolatile memory.

A ninth aspect of the disclosure, alone or in combination with any of the first to third aspects, wherein the memory controller is further configured to perform periodic scrubbing on the plurality of memory blocks independent of the targeted scrubbing operation.

A tenth aspect of the disclosure provides a method of operating a data storage device, comprising: identifying one or more vulnerable memory blocks of a plurality of memory blocks within a nonvolatile memory, the one or more vulnerable memory blocks being suspectable to a bit flip based on an error history of the plurality of memory blocks; and initiating a targeted scrubbing operation to the one or more vulnerable memory blocks.

An eleventh aspect of the disclosure, alone or in combination with the tenth aspect, further comprising scanning the plurality of memory blocks to determine the error history.

A twelfth aspect of the disclosure, alone or in combination with the tenth aspect, wherein the error history comprises historical bit error rate (BER) data of the plurality of memory blocks.

A thirteenth aspect of the disclosure, alone or in combination with any of the tenth to twelfth aspects, wherein the targeted scrubbing operation comprises moving data from the one or more vulnerable memory blocks to one or more other memory blocks of the plurality of memory blocks.

A fourteenth aspect of the disclosure, alone or in combination with any of the tenth to twelfth aspects, wherein the targeted scrubbing operation comprises correcting detected errors using error correction code (ECC) algorithms in the targeted scrubbing operation.

A fifteenth aspect of the disclosure, alone or in combination with any of the tenth to twelfth aspects, further comprising updating a scrubbing timestamp stored in a scrub state file after the targeted scrubbing operation.

A sixteenth aspect of the disclosure, alone or in combination with the fifteenth aspect, further comprising updating error correction outcomes of the one or more vulnerable memory blocks in the nonvolatile memory.

A seventeenth aspect of the disclosure, alone or in combination with the fifteenth aspect, further comprising marking the one or more vulnerable memory blocks in the nonvolatile memory.

An eighteenth aspect of the disclosure, alone or in combination with any of the tenth to twelfth aspects, further comprising performing periodic scrubbing on the plurality of memory blocks independent of the targeted scrubbing operation.

A nineteenth aspect of the disclosure provides a data storage device, comprising: means for identifying one or more vulnerable memory blocks of a plurality of memory blocks within a nonvolatile memory, the one or more vulnerable memory blocks being suspectable to a bit flip based on an error history of the plurality of memory blocks; and means for initiating a targeted scrubbing operation to the one or more vulnerable memory blocks.

A twentieth aspect of the disclosure, alone or in combination with the nineteenth aspect, further comprising: means for performing periodic scrubbing on the plurality of memory blocks independent of the targeted scrubbing operation.

It is to be appreciated that the present disclosure is not limited to the exemplary terms used above to describe aspects of the present disclosure. For example, bandwidth may also be referred to as throughput, data rate, or another term.

Any reference to an element herein using a designation e.g., “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect electrical or other communicative coupling between two structures. Also, the term “approximately” means within ten percent of the stated value.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1. A data storage device comprising:
a nonvolatile memory comprising a plurality of memory blocks; and
a memory controller configured to:
identify one or more vulnerable memory blocks of the plurality of memory blocks, the one or more vulnerable memory blocks being suspectable to a bit flip based on an error history of the plurality of memory blocks, wherein the error history comprises a running error count of detected bit errors aggregated over time; and
initiate a targeted scrubbing operation to the one or more vulnerable memory blocks, prior to a timer used for periodic scrubbing being lapsed.

2. The data storage device of claim 1, wherein the memory controller is further configured to periodically scan the plurality of memory blocks to determine the error history.

3. The data storage device of claim 1, wherein the error history comprises historical bit error rate (BER) data stored in each memory block of the plurality of memory blocks.

4. The data storage device of claim 1, wherein the targeted scrubbing operation comprises moving data from the one or more vulnerable memory blocks to one or more other memory blocks of the plurality of memory blocks.

5. The data storage device of claim 1, wherein the targeted scrubbing operation comprises correcting detected errors using error correction code (ECC) algorithms in the targeted scrubbing operation.

6. The data storage device of claim 1, wherein the memory controller is further configured to update a scrubbing timestamp stored in a scrub state file after the targeted scrubbing operation.

7. The data storage device of claim 6, wherein the memory controller is further configured to update error correction outcomes of the one or more vulnerable memory blocks in the nonvolatile memory.

8. The data storage device of claim 6, wherein the memory controller is further configured to mark the one or more vulnerable memory blocks in the nonvolatile memory.

9. The data storage device of claim 1, wherein the memory controller is further configured to perform periodic scrubbing on the plurality of memory blocks independent of the targeted scrubbing operation.

10. A method of operating a data storage device, comprising:
identifying one or more vulnerable memory blocks of a plurality of memory blocks within a nonvolatile memory, the one or more vulnerable memory blocks being suspectable to a bit flip based on an error history of the plurality of memory blocks, wherein the error history comprises a running error count of detected bit errors aggregated over time; and
initiating a targeted scrubbing operation to the one or more vulnerable memory blocks, prior to a timer used for periodic scrubbing being lapsed.

11. The method of claim 10, further comprising scanning the plurality of memory blocks to determine the error history.

12. The method of claim 10, wherein the error history comprises historical bit error rate (BER) data stored in each memory block of the plurality of memory blocks.

13. The method of claim 10, wherein the targeted scrubbing operation comprises moving data from the one or more vulnerable memory blocks to one or more other memory blocks of the plurality of memory blocks.

14. The method of claim 10, wherein the targeted scrubbing operation comprises correcting detected errors using error correction code (ECC) algorithms in the targeted scrubbing operation.

15. The method of claim 10, further comprising updating a scrubbing timestamp stored in a scrub state file after the targeted scrubbing operation.

16. The method of claim 15, further comprising updating error correction outcomes of the one or more vulnerable memory blocks in the nonvolatile memory.

17. The method of claim 15, further comprising marking the one or more vulnerable memory blocks in the nonvolatile memory.

18. The method of claim 10, further comprising performing periodic scrubbing on the plurality of memory blocks independent of the targeted scrubbing operation.

19. A data storage device, comprising:
means for identifying one or more vulnerable memory blocks of a plurality of memory blocks within a nonvolatile memory, the one or more vulnerable memory blocks being suspectable to a bit flip based on an error history of the plurality of memory blocks, wherein the error history comprises a running error count of detected bit errors aggregated over time; and
means for initiating a targeted scrubbing operation to the one or more vulnerable memory blocks, prior to a timer used for periodic scrubbing being lapsed.

20. The data storage device of claim 19, further comprising:
means for performing periodic scrubbing on the plurality of memory blocks independent of the targeted scrubbing operation.
